(19) United States
(12) Patent Application Publication
(10) Pub. No.: US 2010/0194263 A1
(43) Pub. Date: Aug. 5, 2010

(54) Method for Producing Illuminants Based on Orthosilicates for pcLEDs

(76) Inventors: Holger Winkler, Darmstadt (DE); Tim Vosgroene, Ober-Ramstadt (DE); Gundula Roth, Levenhagen (DE); Walter Tews, Greifswald (DE); Stefan Tews, Greifswald (DE)

Correspondence Address: MILLEN, WHITE, ZELANO & BRANIGAN, P.C., 2200 CLARENDON BLVD., SUITE 1400, ARLINGTON, VA, 22201, US

(21) Appl. No.: 12/594,517

(22) PCT Filed: Mar. 5, 2008
(86) PCT No.: PCT/EP08/01742

§ 371 Date: Apr. 2, 2010

(30) Foreign Application Priority Data
Apr. 4, 2007 (DE) 10 2007 016 228.8

(51) Int. Cl. H01J 63/04; H01J 1/62; H01L 51/54; F21V 9/16; C09K 11/79

(52) U.S. Cl. 313/486; 313/483; 313/503; 313/504; 362/84; 252/301.4 F

(57) ABSTRACT

The invention relates to a process for the preparation of phosphors of the formula I

Ba_{w}SrₓCa_{y}SiO₄:zEu²⁺ (I)

where
w+x+y+z=2 and
0.005≦z≦0.3,

and to an illumination unit and to the use of the phosphor as LED conversion phosphor for white LEDs or so-called colour-on-demand applications.

The invention relates to a wet-chemical process for the preparation of phosphors which consist of europium(II)-doped orthosilicates, preferably alkaline-earth metal orthosilicates, and to the use thereof as LED conversion phosphor for white LEDs or so-called colour-on-demand applications.

The colour-on-demand concept is taken to mean the production of light of a certain colour location by means of a pcLED using one or more phosphors. This concept is used, for example, in order to produce certain corporate designs, for example for illuminated company logos, trademarks, etc.

Recently, phosphors which emit blue-green light, yellow-green to orange light based on excitation in the UV light region or blue light region of the optical spectrum have become ever more important. This is due to the fact that the phosphors can be used for equipment emitting white light. In particular, cerium-doped garnet phosphors (YAG:Ce) are being used in various ways (see, for example, EP 862794, WO 98/12757). However, these have the disadvantage that they only have sufficiently high efficiency at an emission maximum below 560 nm. For this reason, pure YAG:Ce phosphors in combination with blue diodes (450-490 nm) can only be used for the production of cold-white light colours having colour temperatures between 6000 and 8000 K and having comparatively low colour reproduction (typical values for the colour reproduction index Ra are between 70 and 75). This gives rise to greatly restricted application potential. On the one hand, higher demands are generally made of the colour reproduction quality of the lamp on use of white light sources in general lighting, and on the other hand warmer light colours having colour temperatures between 2700 and 5000 K are preferred by consumers, especially in Europe and North America.

WO 00/33389 furthermore discloses the use of, inter alia, Ba₂SiO₄:Eu²⁺ as luminophore for conversion of the light from blue LEDs. However, the maximum of the phosphor emission is at 505 nm, meaning that it is not possible reliably to produce white light using a combination of this type.

Silicate phosphors have been developed in preceding years for white LEDs (see WO 02/11214, WO 02/054502). It is furthermore known that these phosphors can be used for gas discharge lamps (see K. H. Butler “Fluorescent Lamp Phosphors” Pennsylvania Univ. Press, 1980). In addition, T. L. Barry, J. Electrochem. Soc. 1968, 1181, describes that homogeneous, solid mixtures of (Ca,Sr)₂SiO₄:Eu have been systematically researched. These phosphors were prepared by the solid-state diffusion method (mixing & firing method) by mixing oxidic starting materials as powders, grinding the mixture and then calcining the ground powders in a furnace at temperatures up to 1500° C. for up to several days in an optionally reducing atmosphere. As a result, phosphor powders are formed which have inhomogeneities with respect to the morphology, the particle size distribution and the distribution of the luminescent activator ions in the volume of the matrix. Furthermore, the morphology, the particle size distributions and other properties of these phosphors prepared by the traditional process can only be adjusted with difficulty and are hard to reproduce. These particles therefore have a number of disadvantages, such as, in particular, an inhomogeneous coating of the LED chip with these phosphors having non-optimum and inhomogeneous morphology and particle size distribution, which result in high loss processes due to scattering. Further losses occur in production of these LEDs through the fact that the phosphor coating of the LED chip is not only inhomogeneous, but is also not reproducible from LED to LED. This results in variations of the colour locations of the emitted light from the pcLEDs also occurring within a batch.

The LED silicate phosphors are used individually or in a mixture for a blue or UV LED matrix in order to obtain a higher CRI than the YAG:Ce series. In practice, however, the conventional silicate phosphors do not exhibit higher efficiency and illuminance than the YAG:Ce phosphors. In addition, it is reported (see T. L. Barry, J. Electrochem. Soc. 1968, 1181) that some phosphors having a high barium concentration have a problem with hydrolysis sensitivity during use. These deficiencies result in reduced efficiency of the silicate phosphors.

DE 10 2005051063 A1 discloses a silicate-based phosphor having improved emission efficiency which was prepared by wet-chemical methods (wet-grinding and wet-sieving methods) using a nonaqueous organic solvent, such as, for example, ethanol, in order to remove most of the water left in a purification process.

The object of the present invention is therefore to provide alkaline-earth metal orthosilicate phosphors for white LEDs or for colour-on-demand applications which do not have one or more of the above-mentioned disadvantages and produce warm-white light.

Surprisingly, this object is achieved by preparing the alkaline-earth metal orthosilicate phosphors by a wet-chemical process, where a plurality of process variants are possible.

The present invention thus relates to a process for the preparation of phosphors of the formula I

Ba_{w}SrₓCa_{y}Eu_{z}SiO₄ (I)

where
w+x+y+z=2 and
0.005<z<0.5,
characterised in that
a) at least two alkaline-earth metals and a europium-containing dopant in the form of salts, nitrates, oxalates, hydroxides or mixtures thereof are dissolved, dispersed or suspended in water, acids or bases, and
b) a silicon-containing compound is added, and
c) an inorganic or organic precipitation reagent is added to this mixture, and
d) the phosphor precursor forming is converted into the finished phosphor by thermal aftertreatment.
   w, x, y or z here can adopt values between 0 and 2.

The present invention furthermore relates to a process for the preparation of a phosphor of the formula I mentioned above, characterised in that
a) at least two alkaline-earth metals and a europium-containing dopant in the form of salts, nitrates, oxalates, hydroxides or mixtures thereof are dissolved, dispersed or suspended in water, acids or bases, and
b) this solution, dispersion or suspension is added to a silicon-containing mixture and converted into the phosphor precursor at elevated temperatures, and
c) the dried phosphor precursor is subsequently converted into the finished phosphor by thermal aftertreatment.

The alkaline-earth metal starting materials employed are halides, hydroxides or nitrates of barium, strontium and/or calcium in the desired stoichiometric ratio. Preference is given to the use of the corresponding hydroxides or chlorides.

Suitable silicon-containing compounds in the first process are generally inorganic or organic silicon compounds. The inorganic silicon compound used is preferably a finely disperse SiO₂ sol or gel.

The organic silicon compounds employed are preferably precondensed silicic acid esters of the formula Si(OR)₄, where R=methyl, ethyl, propyl, butyl, such as, for example, TES-28® or TES-40® (Wacker). Particular preference is given to the use of Si(OEt)₄.

The term “silicon-containing mixture” is taken to mean a mixture of a dicarboxylic acid, preferably oxalic acid, and an inorganic or organic silicon compound as defined above.

Dopants which can be employed are generally any desired water-soluble europium salts, where europium nitrate and europium chloride are preferred. It is furthermore preferred for the doping concentration of the europium to be between 0.5 and 50 mol %. It is particularly preferably between 2.0 and 20 mol %. At a europium concentration between 10 and 15 mol %, increased absorption and consequently an increased light yield or greater brightness of the phosphor generally arise. A higher europium concentration would reduce the quantum yield and thus in turn result in a reduced light yield.

The wet-chemical processes give the phosphor precursor, which is converted into the finished phosphor by thermal aftertreatment (calcination process).

The following methods are preferred for the wet-chemical pretreatment of an aqueous precursor of the phosphors (“phosphor precursors”) consisting, for example, of a mixture of a barium, strontium and europium halide or hydroxide and a silicon-containing compound:
reaction of the starting materials, preferably alkaline-earth metal hydroxides, with an organosilicon compound, preferably tetraethyl orthosilicate
oxalate precipitation using an inorganic or organic silicon compound, such as SiO₂ or Si(OEt)₄
hydrogencarbonate precipitation using an inorganic or organic silicon compound, such as SiO₂ or Si(OEt)₄

In the first process variant, an organosilicon compound, preferably Si(OEt)₄, is added to, for example, hydroxide solutions of the corresponding phosphor starting materials and a europium-containing dopant at elevated temperatures, causing the formation of the phosphor precursor.

In the second process variant, so-called oxalate precipitation, firstly alkaline-earth metal halides are dissolved in water with a europium halide and added to a silicon-containing mixture consisting of a dicarboxylic acid and an inorganic or organic silicon compound. Increasing the viscosity causes the formation of the phosphor precursor.

In the third process variant, so-called hydrogencarbonate precipitation, firstly the alkaline earth metal starting materials, preferably as alkaline-earth metal halides, are dissolved in water with a europium-containing dopant, and subsequently an inorganic or organic silicon-containing compound is added. Precipitation is carried out using a hydrogencarbonate solution, causing the slow formation of the phosphor precursor.

The thermal aftertreatment of the phosphor precursor to give the finished phosphor is carried out in a thermal reactor or high-temperature furnace by calcination of a defined amount of precursor for a number of hours at temperatures between 1000° C. and 1400° C. in corundum crucibles. The crude phosphor cake is comminuted, washed and sieved. The high-temperature furnace here can be a rotary tubular furnace, chamber furnace, tubular furnace or a fluidised-bed reactor, where a chamber furnace is preferably used.

In the above-mentioned thermal aftertreatment, it is preferred for the calcination to be carried out at least partially under reducing conditions (for example using carbon monoxide, forming gas or hydrogen or at least a vacuum or oxygen-deficiency atmosphere).

The particle size of the phosphors according to the invention is between 50 nm and 50 μm, preferably between 1 μm and 25 μm.

It may furthermore be preferred for an inorganic salt to be added as fluxing agent for lowering the melting point before or during the thermal aftertreatment. Inorganic salts which can be used are chlorides, preferably ammonium chloride, or nitrates or chlorates in an amount of 0.5 to 80%, preferably 1 to 5%, based on the amount of starting material employed.

In a further preferred embodiment, the phosphor has a structured (for example pyramidal) surface on the side opposite an LED chip (see DE 102006054330.0, Merck, which is incorporated into the context of the present application in its full scope by way of reference). This enables as much light as possible to be coupled out of the phosphor.

The structured surface on the phosphor is produced by subsequent coating with a suitable material which has already been structured, or in a subsequent step by (photo)lithographic processes, etching processes or by writing processes using energy or material beams or the action of mechanical forces.

In a further preferred embodiment, the phosphors according to the invention have, on the side opposite an LED chip, a rough surface which carries nanoparticles of SiO₂, TiO₂, Al₂O₃, ZnO₂, ZrO₂ and/or Y₂O₃ or combinations of these materials or of particles comprising the phosphor composition. A rough surface here has a roughness of up to a few 100 nm. The coated surface has the advantage that total reflection can be reduced or prevented and the light can be coupled out of the phosphor according to the invention better (see DE 102006054330.0 (Merck), which is incorporated into the context of the present application in its full scope by way of reference).

It is furthermore preferred for the phosphors according to the invention to have a refractive-index-adapted layer on the surface facing away from the chip, which simplifies the coupling-out of the primary radiation and/or the radiation emitted by the phosphor element.

In a further preferred embodiment, the phosphors have a closed surface coating consisting of SiO₂, TiO₂, Al₂O₃, ZnO, ZrO₂ and/or Y₂O₃ or mixed oxides thereof. This surface coating has the advantage that adaptation of the refractive index to the environment can be achieved through a suitable graduation of the refractive indices of the coating materials. In this case, scattering of the light at the surface of the phosphor is reduced and a greater proportion of the light can penetrate into the phosphor and be absorbed and converted there. In addition, the refractive-index-adapted surface coating enables more light to be coupled out of the phosphor since total internal reflection is reduced.

In addition, a closed layer is advantageous if the phosphor has to be encapsulated. This may be necessary in order to counter sensitivity of the phosphor or parts thereof to diffusing water or other materials in the direct vicinity. A further reason for encapsulation with a closed sheath is thermal decoupling of the actual phosphor from the heat formed in the chip. This heat results in a reduction in the fluorescence light yield of the phosphor and can also affect the colour of the fluorescent light. Finally, a coating of this type enables the efficiency of the phosphor to be increased by preventing lattice vibrations forming in the phosphor from propagating into the environment.

In addition, it is preferred for the phosphors to have a porous surface coating consisting of SiO₂, TiO₂, Al₂O₃, ZnO, ZrO₂ and/or Y₂O₃ or mixed oxides thereof or of the phosphor composition. These porous coatings offer the possibility of further reducing the refractive index of a single layer. Porous coatings of this type can be produced by three conventional methods, as described in WO 03/027015, which is incorporated into the context of the present application in its full scope by way of reference: the etching of glass (for example soda-lime glasses (see U.S. Pat. No. 4,019,884)), the application of a porous layer, and the combination of a porous layer and an etching process.

In a further preferred embodiment, the phosphors have a surface which carries functional groups which facilitate chemical bonding to the environment, preferably consisting of epoxy or silicone resin. These functional groups may be esters or other derivatives which are bonded, for example, via oxo groups and are able to form links to constituents of the binders based on epoxides and/or silicones. Surfaces of this type have the advantage that homogeneous mixing of the phosphors into the binder is facilitated. Furthermore, the rheological properties of the phosphor/binder system and also the pot lives can consequently be adjusted to a certain extent. Processing of the mixtures is thus simplified.

Since the phosphor layer according to the invention applied to the LED chip preferably consists of a mixture of silicone and homogeneous phosphor particles, and the silicone has a surface tension, this phosphor layer is non-uniform at a microscopic level, or the thickness of the layer is not constant throughout.

The present invention furthermore relates to a phosphor of the formula I

Ba_{w}SrₓCa_{y}SiO₄: zEu²⁺ (I)

where
w+x+y+z=2 and
0.005<z<0.5,
prepared by the process according to the invention. This phosphor preferably has a structured surface or a rough surface carrying nanoparticles of SiO₂, TiO₂, Al₂O₃, ZnO, ZrO₂ and/or Y₂O₃ or mixed oxides thereof or of particles comprising the phosphor composition.

It is furthermore preferred for this phosphor of the formula I to have a closed or alternatively porous surface coating consisting of SiO₂, TiO₂, Al₂O₃, ZnO, ZrO₂ and/or Y₂O₃ or mixed oxides thereof.

It may furthermore be preferred for the surface of the phosphor to carry functional groups which facilitate chemical bonding to the environment, preferably comprising epoxy or silicone resin.

With the aid of the above-mentioned processes, any desired outer shapes of the phosphor particles can be produced, such as spherical particles, flakes and structured materials and ceramics.

As a further preferred embodiment, flake-form phosphors are prepared by conventional processes from the corresponding metal and/or rare-earth salts. The preparation process is described in detail in EP 763573 and DE 102006054331.9, which are incorporated into the context of the present application in their full scope by way of reference. These flake-form phosphors can be prepared by coating a natural or synthetically produced, highly stable support or a substrate of, for example, mica flakes, SiO₂ flakes, Al₂O₃ flakes, ZrO₂ flakes, glass flakes or TiO₂ flakes which has a very large aspect ratio, an atomically smooth surface and an adjustable thickness with a phosphor layer by a precipitation reaction in aqueous dispersion or suspension. Besides mica, ZrO₂, SiO₂, Al₂O₃, glass or TiO₂ or mixtures thereof, the flakes may also consist of the phosphor material itself or be built up from a material. If the flake itself serves merely as support for the phosphor coating, the latter must consist of a material which is transparent to the primary radiation from the LED, or absorbs the primary radiation and transmits this energy to the phosphor layer. The flake-form phosphors are dispersed in a resin (for example silicone or epoxy resin), and this dispersion is applied to the LED chip.

The flake-form phosphors can be prepared on a large industrial scale in thicknesses of 50 nm to about 20 μm, preferably between 150 nm and 5 μm. The diameter here is from 50 nm to 20 μm.

It generally has an aspect ratio (ratio of the diameter to the particle thickness) from 1:1 to 400:1 and in particular 3:1 to 100:1.

The flake size (length×width) is dependent on the arrangement. Flakes are also suitable as centres of scattering within the conversion layer, in particular if they have particularly small dimensions.

The surface of the flake-form phosphor according to the invention facing the LED chip can be provided with a coating which has a reflection-reducing action in relation to the primary radiation emitted by the LED chip. This results in a reduction in back-scattering of the primary radiation, enhancing coupling of the latter into the phosphor element according to the invention.

Suitable for this purpose are, for example, refractive-index-adapted coatings, which must have a following thickness d: d=[wavelength of the primary radiation from the LED chip/(4*refractive index of the phosphor ceramic)], see, for example, Gerthsen, Physik [Physics], Springer Verlag, 18th Edition, 1995. This coating may also consist of photonic crystals, which also encompasses structuring of the surface of the flake-form phosphor in order to achieve certain functionalities.

The preparation of the phosphors according to the invention in the form of ceramic elements is carried out analogously to the process described in DE 102006037730 (Merck), which is incorporated into the context of the present application in its full scope by way of reference. The phosphor here is prepared by mixing the corresponding starting materials and dopants by wet-chemical methods, subsequently pressing the mixture isostatically and applying the mixture directly to the surface of the chip in the form of a homogeneous, thin and non-porous flake. No location-dependent variation of the excitation and emission of the phosphor thus takes place, causing the LED provided therewith to emit a homogeneous light cone of constant colour and to have high luminous power. The ceramic phosphor elements can be produced on a large industrial scale, for example, as flakes in thicknesses from a few 100 nm to about 500 μm. The flake size (length×width) is dependent on the arrangement. In the case of direct application to the chip, the size of the flake should be selected in accordance with the chip size (from about 100 μm*100 μm to several mm²) with a certain excess size of about 10%-30% of the chip surface in the case of a suitable chip arrangement (for example flip-chip arrangement) or correspondingly. If the phosphor flake is installed on top of a finished LED, the emitted light cone will be picked up in its entirety by the flake.

The side surfaces of the ceramic phosphor element can be metallised with a light or noble metal, preferably aluminium or silver. The metallisation has the effect that light does not exit laterally from the phosphor element. Light exiting laterally can reduce the light flux to be coupled out of the LED. The metallisation of the ceramic phosphor element is carried out in a process step after isostatic pressing to give rods or flakes, where, if desired, the rods or flakes can be cut to the necessary size before the metallisation. To this end, the side surfaces are wetted, for example with a solution of silver nitrate and glucose, and subsequently exposed to an ammonia atmosphere at elevated temperature. During this operation, a silver coating, for example, forms on the side surfaces.

Alternatively, electroless metallisation processes are suitable, see, for example, Hollemann-Wiberg, Lehrbuch der anorganischen Chemie [Textbook of Inorganic Chemistry], Walter de Gruyter Verlag, or Ullmanns Enzyklopädie der chemischen Technologie [Ullmann's Encyclopaedia of Chemical Technology].

The ceramic phosphor element can, if necessary, be fixed to the substrate of an LED chip using a water-glass solution.

In a further embodiment, the ceramic phosphor element has a structured (for example pyramidal) surface on the side opposite an LED chip. This enables as much light as possible to be coupled out of the phosphor element. The structured surface on the phosphor element is produced by carrying out the isostatic pressing using a mould having a structured press plate and thus embossing a structure into the surface. Structured surfaces are desired if the aim is to produce the thinnest possible phosphor elements or flakes. The pressing conditions are known to the person skilled in the art (see J. Kriegsmann, Technische keramische Werkstoffe [Industrial Ceramic Materials], Chapter 4, Deutscher Wirtschaftsdienst, 1998). It is important that the pressing temperatures used are ⅔ to ⅚ of the melting point of the substance to be pressed.

In addition, the phosphors according to the invention can be excited over a broad range, which extends from about 120 nm to 530 nm, preferably 254 nm to about 480 nm. These phosphors are thus not only suitable for excitation by UV or blue-emitting primary light sources, such as LEDs, or conventional discharge lamps (for example based on Hg), but also for light sources like those which utilise the blue In³⁺ line at 451 nm.

The present invention furthermore relates to an illumination unit having at least one primary light source whose emission maximum or maxima is or are in the range 120 nm to 530 nm, preferably 254 nm to about 480 nm, where the primary radiation is partially or fully converted into longer-wavelength radiation by the phosphors according to the invention.

In accordance with the invention, the term “illumination unit” encompasses the following components or constituents:
at least one primary light source for emitting ultraviolet or blue light,
at least one conversion phosphor which is located in direct or indirect contact with a primary light source,
optionally a transparent sealing resin (for example epoxy or silicone resin) for encapsulation of the illumination unit,
optionally a support component on which the primary light source is mounted and which has at least two electrical connections for the supply of electrical energy for the primary light source,
optionally secondary optical arrangements, such as lenses, mirrors, prisms or photonic crystals.

This illumination unit preferably emits white light or emits light having a certain colour location (colour-on-demand principle). Preferred embodiments of the illumination units according to the invention are described in FIGS. 1 to 12.

In a preferred embodiment of the illumination unit according to the invention, the light source is a luminescent indium aluminium gallium nitride, in particular of the formula InᵢGaⱼAlₖN, where 0≦i, 0≦j, 0≦k, and i+j+k=1. Possible forms of light sources of this type are known to the person skilled in the art. They can be light-emitting LED chips having various structures.

In a further preferred embodiment of the illumination unit according to the invention, the light source is a luminescent arrangement based on ZnO, TCO (transparent conducting oxide), ZnSe or SiC or an arrangement based on an organic light-emitting layer (OLED).

In a further preferred embodiment of the illumination unit according to the invention, the light source is a source which exhibits electroluminescence and/or photoluminescence. The light source may furthermore also be a plasma or discharge source.

The phosphors according to the invention can either be dispersed in a resin (for example epoxy or silicone resin) or, given suitable size ratios, arranged directly on the primary light source or, depending on the application, arranged remote therefrom (the latter arrangement also includes “remote phosphor technology”). The advantages of remote phosphor technology are known to the person skilled in the art and are revealed, for example, in the following publication: Japanese Journ. of Appl. Phys. Vol 44, No. 21 (2005). L649-L651.

In a further embodiment, it is preferred for the optical coupling of the illumination unit between the phosphor and the primary light source to be achieved by a light-conducting arrangement. This enables the primary light source to be installed at a central location and to be optically coupled to the phosphor by means of light-conducting devices, such as, for example, light-conducting fibres. In this way, lamps matched to the illumination wishes and merely consisting of one or different phosphors, which may be arranged to form a light screen, and one or more light conductors, which are coupled to the primary light source, can be achieved. In this way, it is possible to position a strong primary light source at a location which is favourable for the electrical installation and to install lamps comprising phosphors which are coupled to the light conductors at any desired locations without further electrical cabling, but instead only by laying light conductors.

It is furthermore preferred in accordance with the invention for the primary light source, which emits light in the vacuum UV (<200 nm) and/or UV region, to have, in combination with the phosphor according to the invention, an emission band having a half-value width of at least 10 nm.

The present invention furthermore relates to the use of the phosphors according to the invention for partial or complete conversion of the blue or near-UV emission from a luminescent diode.

The phosphors according to the invention are furthermore preferably used for conversion of the blue or near-UV emission into visible white radiation. The phosphors according to the invention are furthermore preferably used for conversion of the primary radiation into a certain colour location in accordance with the “colour-on-demand” concept.

The present invention furthermore relates to the use of the phosphors according to the invention in electroluminescent materials, such as, for example, electroluminescent films (also known as lighting films or light films), in which, for example, zinc sulfide or zinc sulfide doped with Mn²⁺, Cu⁺ or Ag⁺ is employed as emitter, which emit in the yellow-green region. The areas of application of the electroluminescent film are, for example, advertising, display backlighting in liquid-crystal display screens (LC displays) and thin-film transistor (TFT) displays, self-illuminating vehicle licence plates, floor graphics (in combination with a crush-resistant and slip-proof laminate), in display and/or control elements, for example in automobiles, trains, ships and aircraft, or also domestic appliances, garden equipment, measuring instruments or sport and leisure equipment.

The following examples are intended to illustrate the present invention. However, they should in no way be regarded as limiting. All compounds or components which can be used in the compositions are either known and commercially available or can be synthesised by known methods. The temperatures indicated in the examples are always given in ° C. It furthermore goes without saying that, both in the description and also in the examples, the added amounts of the components in the compositions always add up to a total of 100%. Percentage data given should always be regarded in the given connection. However, they usually always relate to the weight of the part-amount or total amount indicated.

### EXAMPLES

### Example 1

### Preparation of the Phosphor Ba_{0.345}Sr_{1.6}Eu_{0.055}Sio₄ by Reaction of Alkaline-Earth Metal Hydroxides with Tetraethyl Orthosilicate

55.18 g of Ba(OH)₂×8H₂O (extra pure grade, Merck KGaA), 212.496 g of Sr(OH)₂×8H₂O (extra pure grade, Merck KGaA) and 10.08 g of EuCl₃×6H₂O (analytical grade ACS, Treibacher Industrie AG) are stirred at 120° C. in an oil bath (precision glass stirrer) in a 500 ml three-necked flask with addition of 20 ml of deionised water. A paste-like consistency is formed. After stirring for a further 60 min, the mixture has low viscosity. 104.164 g of tetraethyl orthosilicate (analytical grade, Merck KGaA) are added rapidly with stirring. The suspension then thickens. A further 20 ml of deionised water are added, then again resulting in a low-viscosity mixture. After 60 min, the heating is switched off, and the mixture is cooled to about 50° C. with stirring.

250 ml of acetone are added, the suspension is slowly cooled to room temp. and stirred overnight.

The precipitate is filtered off with suction and washed with 150 ml of acetone and subsequently dried in vacuo.

### Example 2

### Preparation of the Phosphor Ba_{0.345}Sr_{1.6}Eu_{0.055}SiO₄ from Oxalate Precipitation Using Highly Disperse Silicon Dioxide

126.07 g of oxalic acid dihydrate are dissolved in 1.236 l of deionised water. 12.016 g of silicon dioxide are added. 16.855 g of barium chloride dihydrate (analytical grade, Merck KGaA), 85.288 g of strontium chloride hexahydrate (analytical grade, Merck KGaA) and 4.030 g of europium chloride hexahydrate (analytical grade ACS, Treibacher Industrie AG) are dissolved in 200 ml of deionised water and added dropwise to the oxalic acid dihydrate/silicon dioxide solution with stirring over the course of 30 min. During the dropwise addition, the temperature drops to 15° C. The mixture is then refluxed for 2 h, left to stand overnight in order to cool and filtered with suction on the next day.

The product is dried under a slight vacuum at 75° C. for 24 hours.

### Example 3

### Preparation of the Phosphor Ba_{0.345}Sr_{1.6}Eu_{0.055}SiO₄ from Oxalate Precipitation Using Tetraethyl Orthosilicate

126.07 g of oxalic acid dihydrate are dissolved in 1.236 l of deionised water.

41.66 g of tetraethyl orthosilicate are added. 16.855 g of barium chloride dihydrate (analytical grade ACS, ISO reag. Ph Eur, Merck KGaA), 85.288 g of strontium chloride hexahydrate (analytical grade, Merck KGaA) and 4.030 g of europium chloride hexahydrate (analytical grade ACS, Treibacher Industrie AG) are dissolved in 200 ml of deionised water and added dropwise to the oxalic acid dihydrate/silicon dioxide solution with stirring over the course of 30 min.

At the beginning of the dropwise addition, the temperature drops to 16° C., but then rises on further dropwise addition. The mixture is then refluxed for 3 h, cooled to room temperature and filtered with suction. The product is dried under a slight vacuum at 75° C. for 24 hours.

### Example 4

### Preparation of the Phosphor Ba_{0.345}Sr_{1.6}Eu_{0.055}SiO₄ from Hydrogencarbonate Precipitation Using Highly Disperse Silicon Dioxide

16.9 g of BaCl₂×2H₂O (analytical grade, Merck KGaA), 85.3 g of SrCl₂×6H₂O (analytical grade, Merck KGaA) and 4.0 g of EuCl₃×6H₂O (analytical grade ACS, Treibacher Industrie AG) are dissolved in 360 ml of deionised water in a 1000 ml three-necked flask. 12.0 g of SiO₂ are added. 79.1 g of ammonium hydrogencarbonate are added at 18° C.→vigorous foaming (vigorous evolution of gas) and endothermicity to +7° C.

The resultant suspension is warmed to 88° C. (bath temp. 100° C.) and stirred for 2 hours. The resultant suspension is cooled to 20° C. overnight, and the crystals are filtered off with suction without rinsing. The mother liquor is clear and colourless (pH 9).

### Example 5

### Preparation of the Phosphor Ba_{0.345}Sr_{1.6}Eu_{0.055}SiO₄ from Hydrogencarbonate Precipitation Using Tetraethyl Orthosilicate

16.9 g of BaCl₂×2H₂O (analytical grade, Merck KGaA), 85.3 g of SrCl₂×6H₂O (analytical grade, Merck KGaA), and 4.0 g of EuCl₃×6H₂O (analytical grade ACS, Treibacher Industrie AG) are dissolved in 360 ml of deionised water in a 1000 ml three-necked flask. 41.7 g of tetraethyl orthosilicate (synthetic grade, Merck KGaA) are added. 79.1 g of ammonium hydrogencarbonate are added at 17° C.→vigorous foaming (vigorous evolution of gas) and endothermicity to +7° C. The resultant suspension is warmed to 88° C. (bath temp. 100° C.) and stirred for 2 hours. The resultant suspension is cooled to 20° C. overnight, and the crystals are washed until salt-free and filtered off with suction.

The precursors from Examples 1 and 5 are then converted into the phosphors in a calcination process at 1200° C. which is carried out in a reducing forming-gas atmosphere. To this end, the precursors are introduced into 250 ml corundum crucibles, covered with 5% by weight of ammonium chloride, compacted by shaking and subsequently calcined for 5 hours. The finished crude phosphor cake is subsequently ground in a mortar mill, then washed, dried (T=120° C.) and sieved.

### Comparative Example 6

### Preparation of the Phosphor Ba_{0.345}Sr_{1.6}Eu_{0.055}SiO₄ by a Conventional Solid-State Reaction Method

For 1 mol of phosphor, stoichiometric amounts of BaCO₃, SrCO₃, Eu₂O₃ and SiO₄ corresponding to the above formula composition are ground intensively for 5 h in a ball mill together with 0.2-0.3 mol of NH₄Cl.

The homogeneous starting mixture is introduced into corundum crucibles and brought to reaction at 1200-1400° C. for 3-10 h under a reducing atmosphere (forming gas N₂/H₂).

The resultant crude phosphor is finely ground, washed 4-5 times with deionised water, subsequently filtered and freed from residual moisture at 100° C. in a drying cabinet for several hours. The dried phosphor is drysieved in accordance with the target particle size.

### DESCRIPTION OF THE FIGURES

The invention will be explained in greater detail below with reference to a number of illustrative embodiments. FIGS. 1 to 12 describe various illumination units, all of which contain the orthosilicate phosphors according to the invention:

FIG. 1: shows a diagrammatic drawing of a light-emitting diode with a phosphor-containing coating. The component includes a chip-like light-emitting diode (LED) 1 as radiation source. The light-emitting diode is installed in a cup-shaped reflector, which is held by an adjustment frame 2. The chip 1 is connected to a first contact 6 via a flat cable 7 and directly to a second electrical contact 6′. A coating comprising a conversion phosphor according to the invention has been applied to the inner curvature of the reflector cup. The phosphors are either employed separately from one another or in the form of a mixture. (List of part numbers: 1 light-emitting diode, 2 reflector, 3 resin, 4 conversion phosphor, 5 diffuser, 6 electrodes, 7 flat cable)

FIG. 2: shows a COB (chip on board) package of the InGaN type, which serves as light source (LED) for white light (1=semiconductor chip; 2,3=electrical connections; 4=conversion phosphor; 7=board). The phosphor is distributed in a binder lens, which simultaneously represents a secondary optical element and influences the light emission characteristics as a lens.

FIG. 3: shows a COB (chip on board) package of the InGaN type, which serves as light source (LED) for white light (1=semiconductor chip; 2,3=electrical connections; 4=conversion phosphor; 7=board). The phosphor is located in a thin binder layer distributed directly on the LED chip. A secondary optical element consisting of a transparent material can be placed thereon.

FIG. 4: shows a type of package which serves as light source (LED) for white light (1=semiconductor chip; 2,3=electrical connections; 4=conversion phosphor in cavity with reflector). The conversion phosphor is dispersed in a binder, with the mixture filling the cavity.

FIG. 5: shows a second type of package, where 1=housing plate; 2=electrical connections; 3=lens; 4=semiconductor chip. This design has the advantage of being a flip-chip design, where a greater proportion of the light from the chip can be used for light purposes via the transparent substrate and a reflector on the base. In addition, heat dissipation is favoured in this design.

FIG. 6: shows a package where 1=housing plate; 2=electrical connections; 4=semiconductor chip, and the cavity beneath the lens is completely filled with the conversion phosphor according to the invention. This package has the advantage that a greater amount of conversion phosphor can be used. The latter can also act as remote phosphor.

FIG. 7: shows an SMD package (surface mounted package), where 1=housing; 2,3=electrical connections; 4=conversion layer. The semiconductor chip is completely covered by the phosphor according to the invention. The SMD design has the advantage of having a small physical shape and thus fitting into conventional lights.

FIG. 8: shows a T5 package, where 1=conversion phosphor; 2=chip; 3,4=electrical connections; 5=lens with transparent resin. The conversion phosphor is located on the back of the LED chip, which has the advantage that the phosphor is cooled via the metallic connections.

FIG. 9: shows a diagrammatic drawing of a light-emitting diode, where 1=semiconductor chip; 2,3=electrical connections; 4=conversion phosphor; 5=bond wire, where the phosphor is applied in a binder as top globe. This shape of the phosphor/binder layer can act as secondary optical element and influence, for example, the light propagation.

FIG. 10: shows a diagrammatic drawing of a light-emitting diode, where 1=semiconductor chip; 2,3=electrical connections; 4=conversion phosphor; 5=bond wire, where the phosphor is applied as a thin layer dispersed in a binder. A further component acting as secondary optical element, such as, for example, a lens, can easily be applied to this layer.

FIG. 11: shows an example of a further application, as is already known in principle from U.S. Pat. No. 6,700,322. The phosphor according to the invention is used here together with an OLED. The light source is an organic light-emitting diode 31 consisting of the actual organic film 30 and a transparent substrate 32. The film 30 emits, in particular, blue primary light, produced, for example, by means of PVK:PBD:coumarin (PVK, abbreviation for poly(n-vinylcarbazole); PBD, abbreviation for 2-(4-biphenyl)-5-(4-tert-butylphenyl)-1,3,4-oxadiazole). The emission is partially converted into yellow, secondarily emitted light by a cover layer, formed by a layer 33 of the phosphor according to the invention, producing overall white emission through colour mixing of the primarily and secondarily emitted light. The OLED essentially consists of at least one layer of a light-emitting polymer or of so-called small molecules between two electrodes, which consist of materials known per se, such as, for example, ITO (abbreviation for indium tin oxide), as anode and a highly reactive metal, such as, for example, Ba or Ca, as cathode. A plurality of layers are often also used between the electrodes, which either serve as hole-transport layer or, in the area of small molecules, also serve as electron-transport layers. The emitting polymers used are, for example, polyfluorenes or polyspiro materials.

FIG. 12: shows a low-pressure lamp 20 with a mercury-free gas filling 21 (diagrammatic), which comprises an indium filling and a buffer gas analogously to WO 2005/061659, where a layer 22 of the phosphors according to the invention is applied.

FIG. 13: shows a comparison of the excitation spectra of: 1=phosphor Ba_{0.345}Sr_{1.6}Eu_{0.055}SiO₄ according to the invention, prepared by hydrogencarbonate precipitation; 2=phosphor of the same composition as under 1, prepared by the conventional solid-state reaction method (see Comparative Example 6).

FIG. 14: shows a comparison of the emission spectra of: 1=phosphor Ba_{0.345}Sr_{1.6}Eu_{0.055}SiO₄ according to the invention, prepared by hydrogencarbonate precipitation; 2=phosphor of the same composition as under 1, prepared by the conventional solid-state reaction method. Phosphor 2 has a higher light intensity or light yield than phosphor 1.

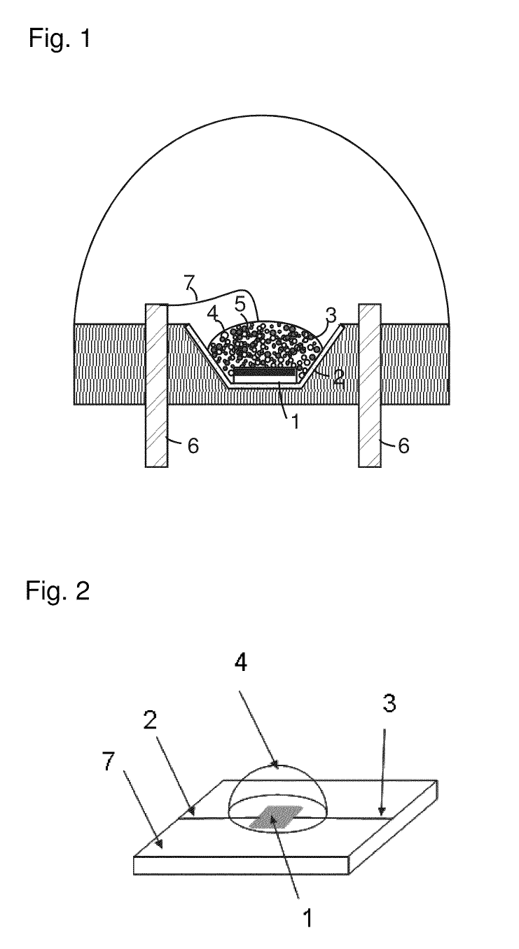

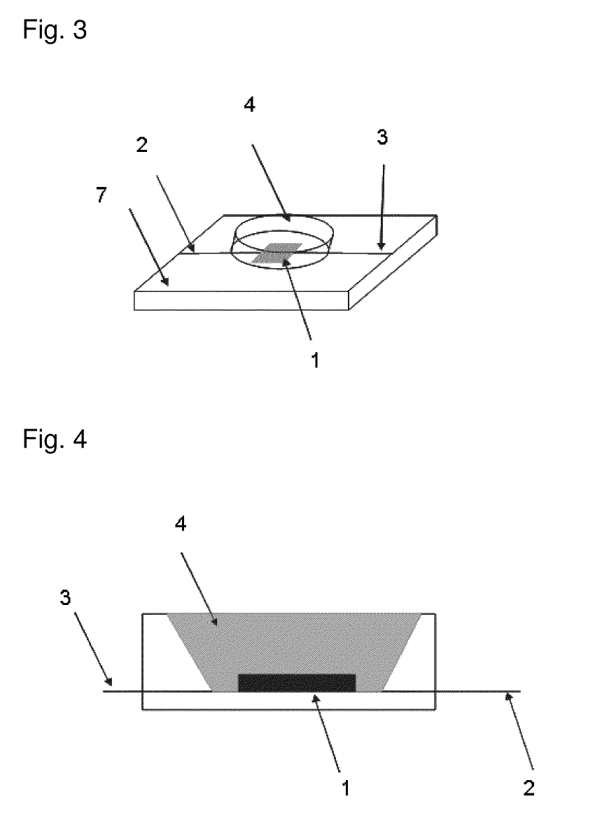

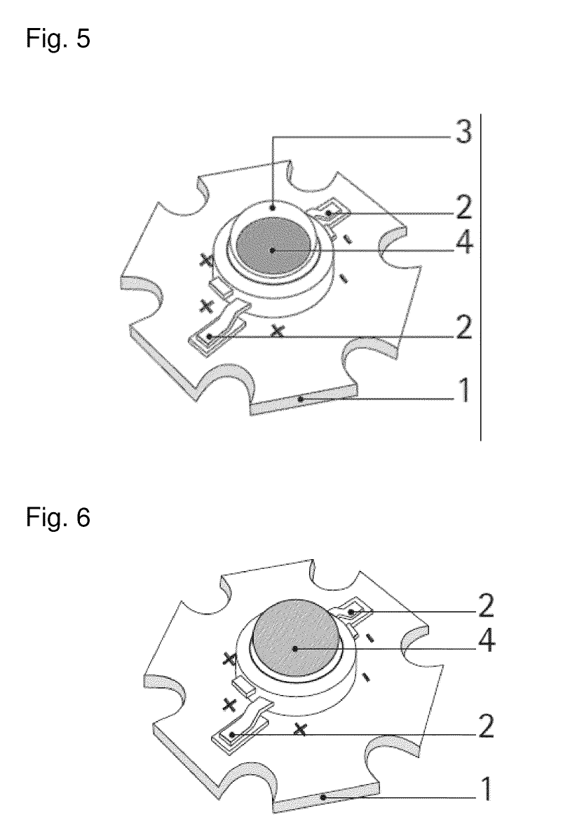

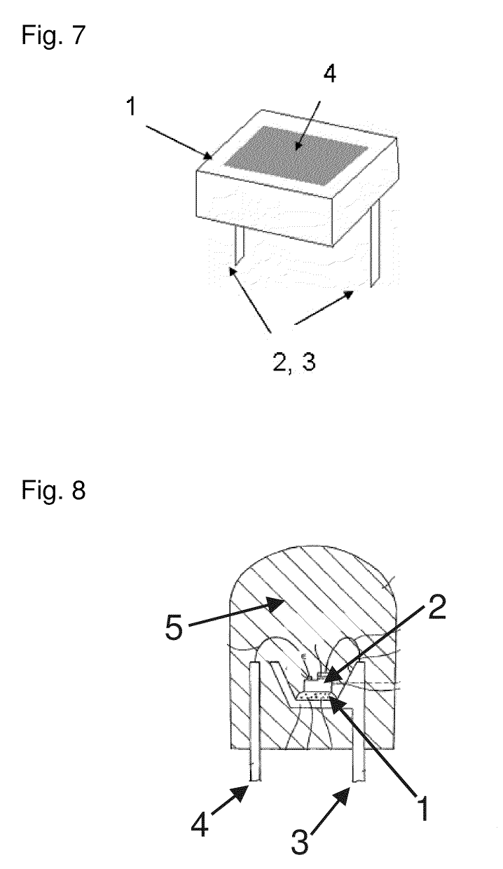

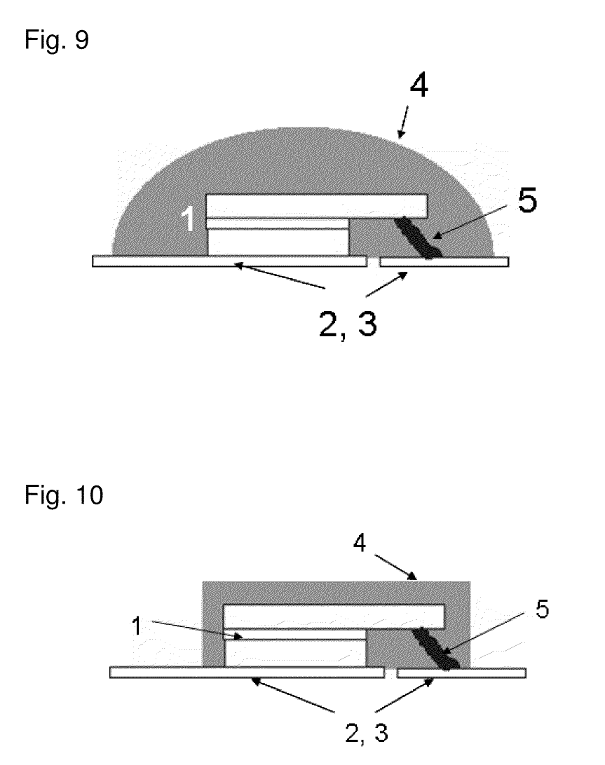

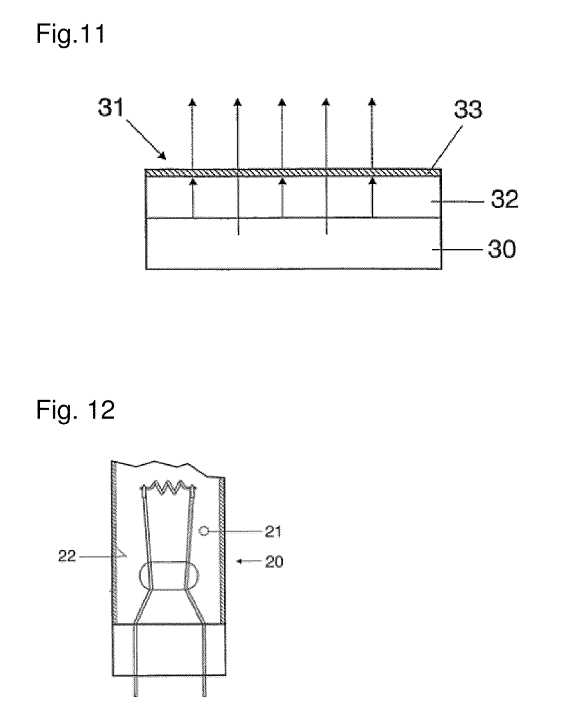

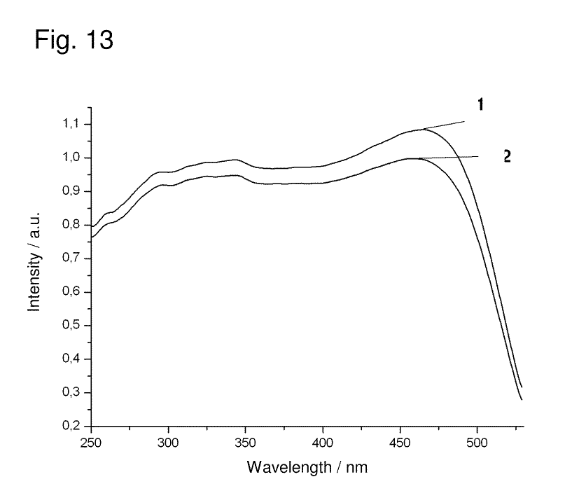

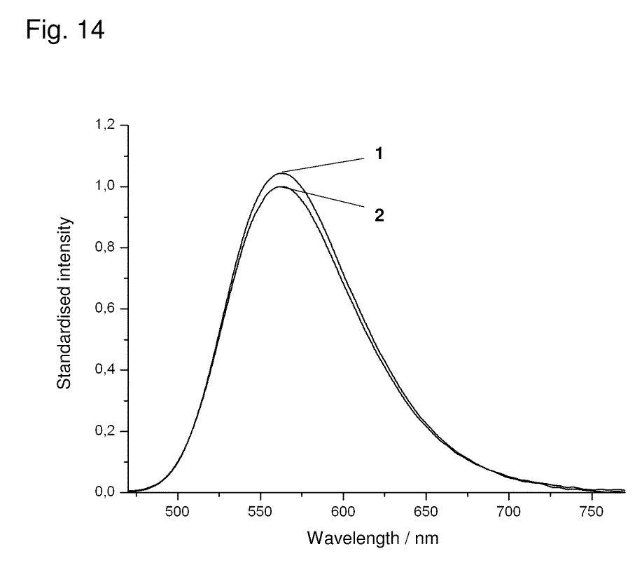

1. Process for the preparation of a phosphor of the formula I
Ba_{w}SrₓCa_{y}SiO₄:zEu²⁺ (I)
where
w+x+y+z=2,
0.005<z<0.5,
characterised in that
a) at least two alkaline-earth metals and a europium-containing dopant in the form of salts, nitrates, oxalates, hydroxides or mixtures thereof are dissolved, dispersed or suspended in water, acids or bases, and
b) this solution, dispersion or suspension is added to a silicon-containing mixture and converted into the phosphor precursor at elevated temperatures, and
c) the dried phosphor precursor is subsequently converted into the finished phosphor by thermal aftertreatment.

2. Process according to claim 1, characterised in that an inorganic salt is added as fluxing agent before or during the thermal aftertreatment.

3. Process according to claim 1, characterised in that the silicon-containing compound is an organosilicon compound, preferably a silicic acid ester.

4. Process according to claim 1, characterised in that the silicon-containing compound is an inorganic silicon compound, preferably a finely disperse SiO₂ sol or gel.

5. Process according to claim 2, characterised in that the silicon-containing mixture consists of a dicarboxylic acid, preferably oxalic acid, and an inorganic silicon compound, preferably silicon dioxide.

7. Process according to claim 2, characterised in that the silicon-containing mixture consists of a dicarboxylic acid, preferably oxalic acid, and an organosilicon compound, preferably a silicic acid ester.

8. Process according to claim 1, characterised in that the thermal aftertreatment is carried out in a reducing forming-gas atmosphere.

9. Process according to claim 1, characterised in that the thermal aftertreatment is carried out in a thermal reactor, such as a rotary tubular furnace, chamber furnace or tubular furnace, or in a fluidised-bed reactor.

10. Process according to claim 1, characterised in that the surface of the phosphor is additionally structured.

11. Process according to claim 1, characterised in that the phosphor is additionally provided with a rough surface which carries nanoparticles of SiO₂, TiO₂, Al₂O₃, ZnO, ZrO₂ and/or Y₂O₃ or mixed oxides thereof or of the phosphor composition.

12. Process according to claim 1, characterised in that the surface of the phosphor is additionally provided with a closed coating of SiO₂, TiO₂, Al₂O₃, ZnO, ZrO₂ and/or Y₂O₃ or mixed oxides thereof.

13. Process according to claim 1, characterised in that the surface of the phosphor is provided with a porous coating of SiO₂, TiO₂, Al₂O₃, ZnO, ZrO₂ and/or Y₂O₃ or mixed oxides thereof or of the phosphor composition.

14. Process according to claim 1, characterised in that the surface of the phosphor is additionally provided with functional groups which facilitate chemical bonding to the environment, preferably comprising epoxy or silicone resin.

15. Phosphor of the formula I
Ba_{w}SrₓCa_{y}SiO₄: zEu²⁺ (I)
where
w+x+y+z=2,
0.005<z<0.5,
prepared according to claim 1, characterised in that it has a structured surface.

16. Phosphor according to claim 15, characterised in that it has a rough surface which carries nanoparticles of SiO₂, TiO₂, Al₂O₃, ZnO, ZrO₂ and/or Y₂O₃ or mixed oxides thereof or particles comprising the phosphor composition.

17. Phosphor according to claim 15, characterised in that it has a closed surface coating consisting of SiO₂, TiO₂, Al₂O₃, ZnO, ZrO₂ and/or Y₂O₃ or mixed oxides thereof.

18. Phosphor according to claim 15, characterised in that it has a porous surface coating consisting of SiO₂, TiO₂, Al₂O₃, ZnO, ZrO₂ and/or Y₂O₃ or mixed oxides thereof.

19. Phosphor according to claim 10, characterised in that the surface carries functional groups which facilitate chemical bonding to the environment, preferably consisting of epoxy or silicone resin.

20. Illumination unit having at least one primary light source whose emission maximum is in the range 120 to 530 nm, preferably between 254 nm and 480 nm, where this radiation is partially or fully converted into longer-wavelength radiation by a phosphor according to claim 15.

21. Illumination unit according to claim 20, characterised in that the light source is a luminescent indium aluminium gallium nitride, in particular of the formula InᵢGaⱼAlₖN, where 0≦i, 0≦j, 0≦k, and i+j+k=1.

22. Illumination unit according to claim 20, characterised in that the light source is a luminescent compound based on ZnO, TCO (transparent conducting oxide), ZnSe or SiC.

23. Illumination unit according to claim 20, characterised in that the light source is a material based on an organic light-emitting layer.

24. Illumination unit according to claim 20, characterised in that the light source is a source which exhibits electroluminescence and/or photoluminescence.

25. Illumination unit according to claim 20, characterised in that the light source is a plasma or discharge source.

26. Illumination unit according to claim 20, characterised in that the phosphor is arranged directly on the primary light source and/or remote therefrom.

27. Illumination unit according to claim 20, characterised in that the optical coupling between the phosphor and the primary light source is achieved by a light-conducting arrangement.

28. Illumination unit according to claim 20, characterised in that the primary light source, which emits light in the vacuum UV and/or UV and/or blue and/or green region of the visible spectrum, has, in combination with said phosphor, an emission band having a half-value width of at least 10 nm.

29. A method comprising using at least one phosphor of the formula I according to claim 15 as conversion phosphor for partial or complete conversion of the blue or near-UV emission from a luminescent diode.

30. A method comprising using at least one phosphor of the formula I according to claim 15 as conversion phosphor for conversion of the primary radiation into a certain colour point in accordance with the colour-on-demand concept.

31. A method of comprising using at least one phosphor of the formula I according to claim 15 for conversion of the blue or near-UV emission into visible white radiation.
